(19) United States
(12) Patent Application Publication
(10) Pub. No.: US 2008/0204677 A1
(43) Pub. Date: Aug. 28, 2008

(54) PATTERN FORMING METHOD

(76) Inventor: Shinichi ITO, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/037,492

(22) Filed: Feb. 26, 2008

(30) Foreign Application Priority Data
Feb. 26, 2007 (JP) 2007-045897

(51) Int. Cl. G03B 27/52; G03F 7/26

(52) U.S. Cl. 355/27; 430/322

(57) ABSTRACT

In a pattern forming method of forming a desired pattern on a resist film on a substrate, the surface of a substrate is subjected to a surface hydrophobizing process to form a processed film for improving the adhesion of the surface of the substrate to resist, a coating film including at least a resist film is formed on the processed film, the resist film is exposed to form a desired pattern, and the pattern-formed resist film is developed. In addition to this, the processed film formed on the underside of the substrate by the surface hydrophobizing process is removed between the time from the formation of the processed film and the exposure of the resist film.

### CROSS-REFERENCE TO RELATED APPLICATIONS

This application is based upon and claims the benefit of priority from prior Japanese Patent Application No. 2007-045897, filed Feb. 26, 2007, the entire contents of which are incorporated herein by reference.

### BACKGROUND OF THE INVENTION

1. Field of the Invention

This invention relates to a pattern forming method of forming a resist pattern on a substrate, and more particularly to a pattern forming method which includes the process of removing a processed film formed on a substrate by an adhesion process for improving adhesion.

2. Description of the Related Art

To improve the adhesion of a resist pattern to a substrate, a surface hydrophobizing process has been carried out using HMDS (hexamethyldisilazane). This process is a method of causing HMDS to act on hydroxyl existing on the substrate to silylate the surface of the substrate. Not only is a silazane compound, such as HMDS, caused to act on the substrate, but also the substrate is heated, thereby hydrophobizing the surface.

For example, in a sealed chamber, a substrate is placed above a heat plate with a gap of about 100 μm between them. In this state, while the substrate is being heated, a silazane compound, such as HMDS, is supplied to the surface of the substrate. When the surface is silylated in this way, the silazane flows through the gap to the underside of the substrate, with the result that the underside of the substrate is also silylated. When such a substrate is set on a resist film spin-coating apparatus and processed, the silylated area of the underside of the substrate makes contact with a spin chuck, causing a problem: dust is caused in the contact area. Moreover, when exposure is made with an exposure device after the resist film is formed, the following problem arises: when the silylated area comes into contact with the chuck pin of the exposure device, this causes dust.

Those dusting phenomena increase particles in each of the coating development apparatus and exposure device. For this reason, it takes a lot of time for maintenance work, such as the cleaning of the chuck.

Furthermore, a method of removing the processed film formed on the periphery of the substrate by the adhesion process by applying ultraviolet rays to the film has been proposed (Jpn. Pat. Appln. KOKAI Publication No. 2003-318007). However, in the document, the way of dealing with the processed film formed on the underside of the substrate has not been disclosed at all. Moreover, a method of exposing the resist attached to the underside of the substrate and then developing the resist, thereby removing the resist has been proposed (Jpn. Pat. Appln. KOKAI Publication No. 2001-68393). With this method, however, although the resist can be removed, it is difficult to remove the processed film under the resist.

### BRIEF SUMMARY OF THE INVENTION

According to an aspect of the invention, there is provided a pattern forming method comprising: subjecting the surface of a substrate to a surface hydrophobizing process to form a processed film for improving the adhesion of the surface of the substrate to resist; forming on the processed film a coating film including at least a resist film; exposing the resist film to form a desired pattern; developing the pattern-formed resist film; and removing the processed film formed on the underside of the substrate by the surface hydrophobizing process, between the formation of the processed film and the exposure of the resist film.

According to another aspect of the invention, there is provided a pattern forming method comprising: not only heating a substrate from below the underside of the substrate with a heat plate and supplying a material gas for a surface hydrophobizing process to the surface of the substrate but also exhausting the material gas from outside the periphery of the substrate and further exhausting the material gas flowed to the underside of the substrate, thereby forming a processed film on the surface of the substrate to improve the adhesion of the substrate to a resist film; causing the central part of the underside of the substrate to stick fast to a turntable and rotating the substrate and, at the same time, supplying hydrofluoric acid solution, ammonium fluoride solution, hydrofluoric acid gas, or ammonium fluoride gas to the underside of the substrate, thereby removing the processed film formed on the underside of the substrate by the surface hydrophobizing process; forming on the processed film a coating film including at least a resist film; exposing the resist film to form a desired pattern; and developing the pattern-formed resist film.

According to still another aspect of the invention, there is provided a processed film forming apparatus comprising: a heat plate which is provided in a container and which has a substrate placed above the plate with a specific gap between the plate and the underside of a substrate and heats the substrate from below the underside; a gas supplying mechanism which supplies to the surface of the substrate a processed film material gas for improving the adhesion of the substrate to resist; a first gas exhaust mechanism which exhausts the gas supplied to the surface of the substrate from outside the periphery of the substrate; and a second gas exhaust mechanism which is provided at the underside of the substrate and exhausts the material gas flowed to the underside of the substrate.

### BRIEF DESCRIPTION OF THE SEVERAL VIEWS OF THE DRAWING

FIG. 1 is a flowchart to help explain a resist pattern forming method according to a first embodiment of the invention;

FIG. 2 is a sectional view showing a schematic configuration of an HDMS film forming apparatus used in the first embodiment;

FIG. 3 is plan view showing the positional relationship between a substrate and exhaust pipes in the film forming apparatus of FIG. 2;

FIG. 4 is a sectional view showing a schematic configuration of a processed film removing apparatus used in the first embodiment;

FIG. 5 is a sectional view showing the stage part of an exposure device used in the first embodiment;

FIG. 6 is a flowchart to help explain a resist pattern forming method according to a second embodiment of the invention;

FIGS. 7A and 7B are sectional views to help explain modifications of the embodiments;

FIG. 8 shows the way dust is caused as a result of the friction between a silylated layer and a spin chuck; and

FIG. 9 shows the way dust is caused as a result of the friction between a silylated layer and the chuck pins of an exposure device.

### DETAILED DESCRIPTION OF THE INVENTION

Hereinafter, referring to the accompanying drawings, embodiments of the invention will be explained.

### First Embodiment

FIG. 1 is a flowchart to help explain a resist pattern forming method according to a first embodiment of the invention.

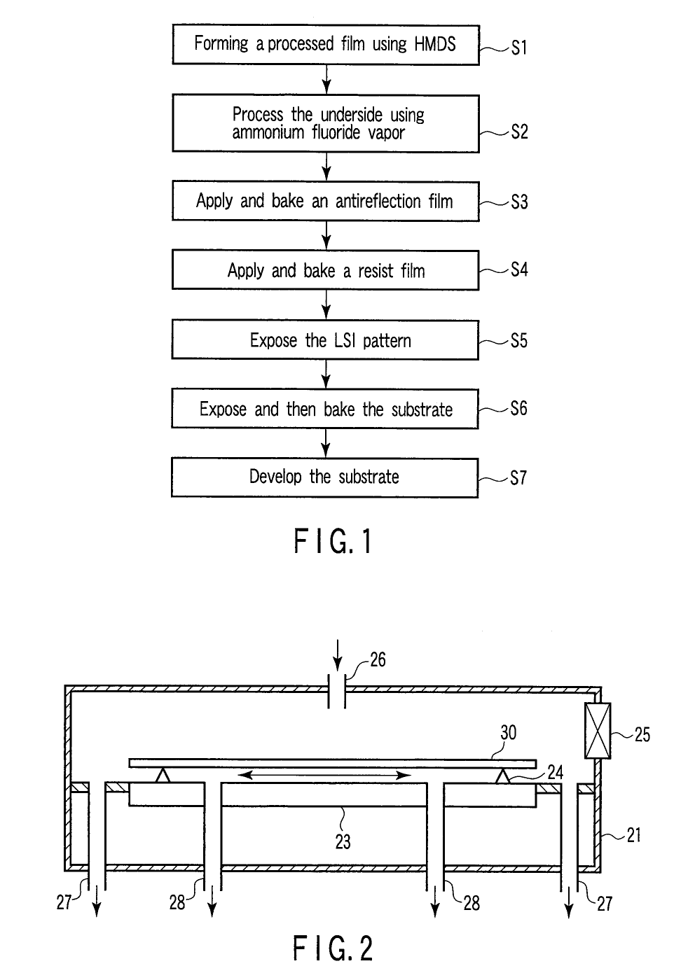

First, using HMDS (hexamethyldisilazane), a substrate is subjected to a surface hydrophobizing process, thereby forming a processed film on the substrate to improve the adhesion of the substrate to resist (step S1). To form the processed film, an HMDS film forming apparatus as shown in FIG. 2 is used.

In the HMDS film forming apparatus of the first embodiment, a heat plate 23 is placed in an air-tight chamber 21 and a substrate 30 is put above the heat plate 23. To perform heat treating uniformly, the substrate 30 is supported by gap pins 24 in such a manner that a gap of about 50 to 100 μm is made between the substrate and the heat plate 23. On the side of the chamber 21, there is provided a gate 25 for carrying in and out the substrate 30.

In the central part of the top face of the chamber 21, a silazane compound introducing pipe 26 is provided. A silazane compound is introduced through the introducing pipe 26 into the chamber 21. The gas in the chamber 21 is exhausted from first exhaust pipes 27 provided outside the periphery of the substrate 30.

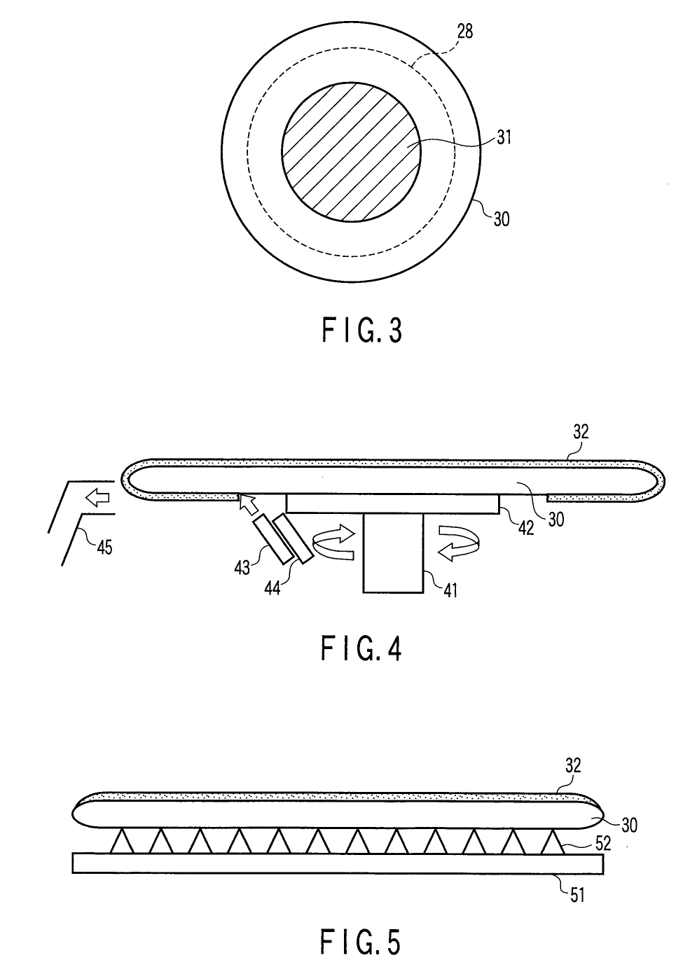

The basic configuration explained above is the same as that of a general film forming apparatus. In the first embodiment, second exhaust pipes 28 are further provided in positions facing the underside of the substrate 30 in such a manner that the pipes penetrate the heat plate 23. Specifically, as shown in FIG. 3, a plurality of exhaust pipes 28 are provided along a concentric circle having the same center as that of the substrate 3. Moreover, the exhaust pipes 28 are located outside a chuck contact area 31 at the time of removal of the processed film explained later and inside the periphery of the substrate 30.

The positions in which the exhaust pipes 28 are formed are not limited to the above positions. For example, the exhaust pipes 28 may be located in positions facing the underside near the edge of the substrate 30. A plurality of exhaust pipes 28 may be arranged in the radial direction. Moreover, the exhaust pipes 28 do not necessarily penetrate the heat panel 23. They have only to be provided so as to sufficiently exhaust the air at the underside of the substrate 30. For example, the exhaust pipes 28 may be provided outside the periphery of the substrate 30 in such a manner that the outlets of the exhaust pipes 28 point to the underside of the substrate 30.

Using the film forming apparatus of FIG. 2, the substrate 30 is placed above the heat plate 23 in the air-tight chamber 21 with a gap of about 100 μm between the substrate 30 and the heat plate 23. In this state, while the substrate is being heated, a silazane compound, such as HMDS, is supplied from the introducing pipe 26 into the chamber 21, thereby forming a processed film on the surface of the substrate 30. At this time, the silazane compound flows to the underside of the substrate 30, with the result that a processed film is also formed on the underside of the substrate 30. However, since the exhaust pipes 28 have been provided so as to prevent HMDS from reaching the part with which the chuck of a subsequent device makes contact, the processed film has not been formed on the entire underside of the substrate and has been formed outside the chuck contact area 31.

Next, using a processed film removing apparatus shown in FIG. 4, the processed film is removed (step S2). The film removing apparatus is composed of a spinner 41 which rotates the substrate 30 in spin-coating the substrate 30, the chuck part (turntable) 42 of the spinner, a process atmosphere supplying apparatus 43, an underside water-washing port 44, and an atmosphere recovery port 45.

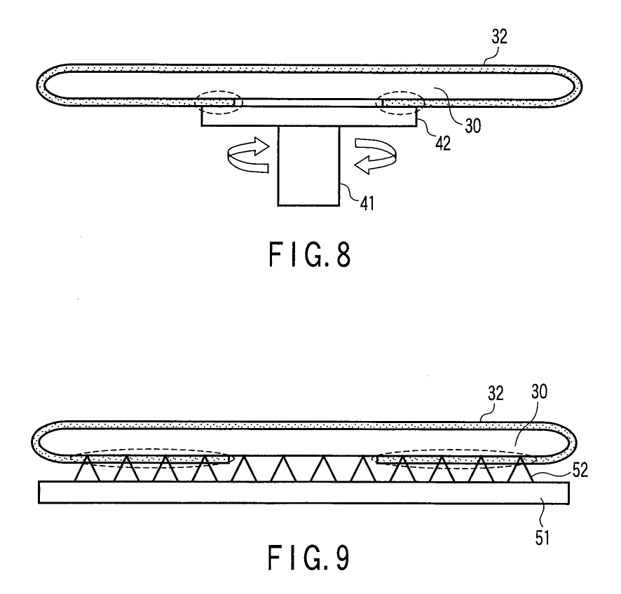

The substrate 30 is placed on the chuck part 42 and the central part of the underside of the substrate 30 is fixed to the chuck part 42. In the first embodiment, to prevent a processed film from being formed in the chuck contact area 31 with the processed film forming apparatus of FIG. 2, exhausting is done outside the area 31. Accordingly, there is no silylated layer 32 in the chuck area and therefore the substrate is fixed in place in a good condition without the generation of particles. If the exhaust pipes 28 were not provided in the HDMS film forming apparatus, or if the chuck part 42 were larger than the chuck contact area 31, the silylated layer 32 formed on the underside of the substrate 30 would come into contact with the chuck part 42, as shown in the part that enclosed it with dotted line in FIG. 8. And dust would be caused in the contact area. In the first embodiment, use of the film forming apparatus of FIG. 2 prevents such dust from being caused.

With the apparatus of FIG. 4, while the substrate 30 is being rotated, an ammonium fluoride atmosphere is caused to act on the underside silylated layer formation area. The ammonium fluoride atmosphere is supplied to the underside of the substrate in such a manner that nitrogen gas is introduced into ammonium fluoride solution, thereby causing the nitrogen gas to absorb ammonium fluoride. The nitrogen gas including ammonium fluoride is collected by the atmosphere recovery port 45 provided around the substrate. Then, purified water is supplied from the underside water-washing port 44 to the underside, thereby removing the silylated layer reacted with ammonium fluoride. The purified water is also collected by the atmosphere recovery port 45.

By this process, the silylated layer 32 formed in the edge part is removed from the underside of the substrate 30. Since neither an antireflection film nor a resist film has been formed on the silylated layer 32, the silylated layer 32 is removed efficiently.

Next, after antireflection film material (e.g., ARC29a made by Nissan Chemical Industries, Ltd) is applied to the surface of the substrate 30 and then the substrate is baked, thereby forming an antireflection film (step S3).

Next, after resist film material (e.g., TARF-P611 made by Tokyo Ohka Kogyo Co., Ltd) is applied to the surface of the substrate 30 and then the substrate is baked, thereby forming a resist film (step S4).

The diameter of the spin chuck used for the coating of the antireflection film and resist film is larger than that of the spin chuck mounted on the processed film removing apparatus of FIG. 4. In this case, too, since the silylated layer formed on the underside of the substrate as far as the edge part has already removed, it is possible to prevent dust from being caused without fastening the silylated layer to the chuck.

Next, the LSI pattern is exposed with the exposure device (step S5). As shown in FIG. 5, many chuck pins 52 are provided on a stage 51 of the exposure device in such a manner that they are located toward the outer diameter of the substrate outside the exhaust area for forming a silylated layer nonformation area with the preceding processed film forming apparatus. However, since the processed film removing apparatus has already removed the silylated layer formed on the underside of the substrate as far as the edge part, the chuck pints 52 of the exposure stage 51 do not make contact with the silylated film, preventing dust from being caused.

If the silylated layer 32 on the underside of the substrate 30 has not been removed by the processed film removing apparatus of FIG. 4, the silylated layer 32 formed on the underside of the substrate 30 comes into contact with the chuck pints 52 as shown by the part enclosed by the broken lines in FIG. 9. In this case, dust is caused in the area where the silylated layer 32 contacts the chuck pins 52. In the first embodiment, before exposure, the silylated layer 32 on the underside of the substrate is removed by the processed film removing apparatus of FIG. 4, thereby preventing dust from being caused.

Next, the pattern-exposed substrate 30 is further baked after exposure (step S6).

Next, the substrate is developed, thereby forming a resist pattern (step S7). At this time, the resist pattern is formed, while the generation of dust from the substrate 30 is being suppressed.

As described above, with the first embodiment, since the silylated layer formed on the underside of the substrate is removed immediately after the formation of a processed film using HMDS, it is possible to prevent not only the chuck part of the coating development apparatus but also the chuck part of the exposure device from being contaminated. That is, after a silazane compound, such as HMDS, is caused to act on the main surface of the substrate to form a processed film (silylated film), the processed film (silylated film) formed on the underside is removed, thereby preventing the chucks of the exposure device from being contaminated. Furthermore, in the tracks, too, the chucks, such as the spin chucks, are prevented from being contaminated.

Specifically, the processed film inevitably formed on the underside of the substrate 30 in a surface hydrophobizing process to improve the adhesion of the surface of the substrate can be removed before pattern exposure. This makes it possible to suppress the generation of particles and therefore help prevent the exposure device and the coating development apparatus from being contaminated.

While in the first embodiment, HMDS has been used for silylation, the invention is not limited to this. For instance, the invention produces a sufficient effect when using a film made of a processed film forming material which includes disilazane (Si—NH), such as tetramethyldisilazane (TMDS).

Furthermore, when it is difficult to remove the processed film in an ammonium fluoride atmosphere, the processed film may be removed in an atmosphere of a mixture of hydrofluoric acid and ammonium fluoride. Moreover, the process is carried out using hydrofluoric acid, thereby removing not only the silylated layer but also the oxide film on the underside of the substrate, which suppresses the generation of dust. In addition, to remove the processed film more reliably, plasma etching in an atmosphere of the above gas may be used.

When the exhaust pipes 28 are arranged almost in positions facing the underside of the edge boundary of the substrate 30, the exhaust capability is sufficient, and control is performed so as to prevent the silazane compound from running over the edge and reaching the inner part of the underside, the process of removing the processed film formed on the underside may be eliminated.

### Second Embodiment

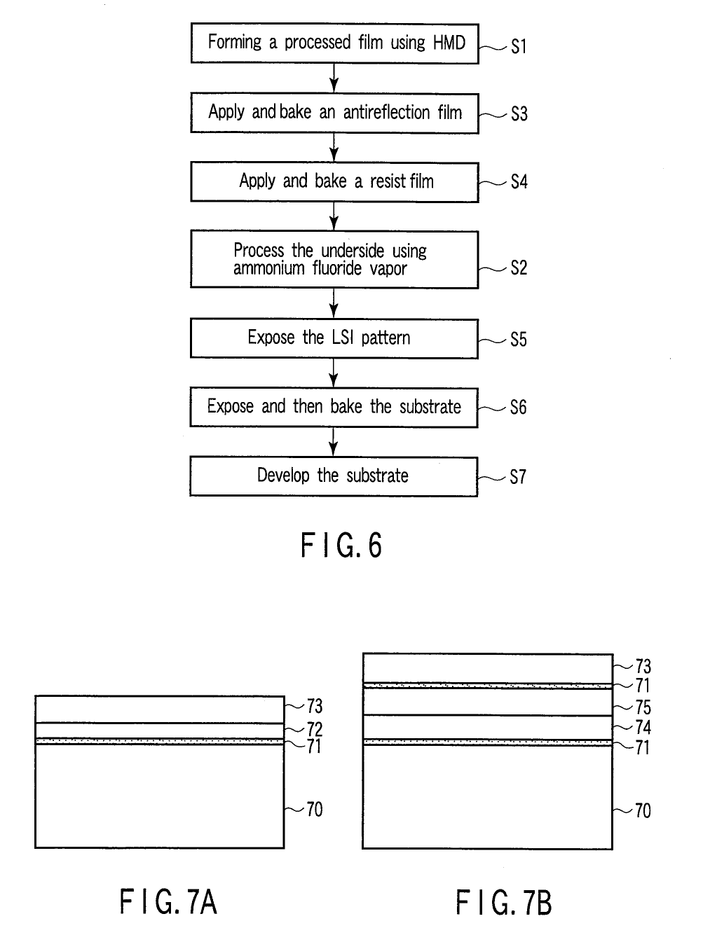

FIG. 6 is a flowchart to help explain a resist pattern forming method according to a second embodiment of the invention.

The second embodiment differs from the first embodiment in that the step (S2) of removing the processed film 32 is carried out after the step (S3) of forming an antireflection film and the step (S4) of forming a resist film.

In the second embodiment, the processed film 32 is not formed in the chuck contact area 31 on the underside of the substrate 30 as a result of using the film forming apparatus of FIG. 2. Therefore, when the chuck unit of the antireflection film and resist forming apparatus is caused to make contact with the inner part of the chuck contact area 31, the chuck unit dose not come into contact with the silylated layer 32 in forming an antireflection film and a resist film, which causes no dust.

Specifically, when the processed film forming boundary is located outside the chuck unit used in forming an antireflection film and a resist film, the processed film on the underside may be removed immediately before the exposure process as in the second embodiment. That is, the processed film may be removed at any time between the formation of the processed film and the exposure of the resist film.

(Modification)

The invention is not limited to the above embodiments. While in the embodiments, the processed film on the underside of the substrate have been removed by exposing the film to hydrofluoric acid or an ammonium fluoride atmosphere, the invention is not restricted to this. When the process has to be carried out in a short time, the underside of the substrate is exposed to hydrofluoric acid solution, or ammonium fluoride solution, or a mixture of these solutions, realizing a process performed in several to several tens of seconds, which improves the productivity. The apparatus used for this purpose has only to have the same mechanism as that of the apparatus used to wash the underside of the development apparatus.

Furthermore, in the embodiments, when a processed film has been formed on the substrate, the new processed film forming apparatus of FIG. 2 has been used to prevent the processed film from being formed in the area of the underside of the substrate with which the chuck part has made contact. However, an existing processed film forming apparatus may be used as it is, provided that the processed film forming condition is optimized in the existing film forming apparatus and a processed film forming boundary is set outside the area with which the chuck part of the processed film removing apparatus makes contact.

Moreover, in the embodiments, as shown in FIG. 7A, after the processed film 71 has been formed on the surface of the substrate 70, the antireflection film 72 and resist film 73 have been formed on the processed film 71. However, if reflection is not a problem as in electron beam exposure or EUV exposure, a resist film 73 may be formed directly on the processed film 71. In addition, as shown in FIG. 7B, a planarizing organic lower layer film 74 and an SOG film 75 may be formed as a pattern transfer film on a substrate 70 and, on the resulting film, a resist film 73 may be formed. In this method, the processed film 71 is formed by an adhesion process serving as a pre-step for the formation of the lower layer 74 and an adhesion process serving as a pre-step for the formation of the resist film 73. In this case, too, the process of forming the processed film 71 and the process of removing the processed film 71 are carried out as in the first and second embodiments. That is, the processed film formed on the substrate has only to be removed by the surface hydrophobizing process between the formation of the processed film and the exposure of the resist film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming method comprising:
subjecting the surface of a substrate to a surface hydrophobizing process to form a processed film for improving the adhesion of the surface of the substrate to resist;
forming on the processed film a coating film including at least a resist film;
exposing the resist film to form a desired pattern;
developing the pattern-formed resist film; and
removing the processed film formed on the underside of the substrate by the surface hydrophobizing process, between the formation of the processed film and the exposure of the resist film.

2. The pattern forming method according to claim 1, wherein the processed film is composed of a silazane compound film.

3. The pattern forming method according to claim 1, wherein said removing the processed film includes causing the central part of the underside of the substrate to stick fast to a turntable and rotating the substrate and, at the same time, supplying hydrofluoric acid solution, ammonium fluoride solution, hydrofluoric acid gas, or ammonium fluoride gas to the underside of the substrate.

4. The pattern forming method according to claim 3, wherein said forming a processed film includes not only heating the substrate from below the underside of the substrate and supplying material gas to the surface of the substrate but also exhausting the material gas from outside the periphery of the substrate and further exhausting the material gas flowed to the underside of the substrate.

5. The pattern forming method according to claim 4, wherein said exhausting the material gas flowed to the underside of the substrate includes exhausting the material gas outside the area where the underside of the substrate sticks fast to the turntable and inside the periphery of the substrate, when removing the processed film.

6. The pattern forming method according to claim 1, wherein said forming a coating film includes forming the resist film directly on the processed film.

7. The pattern forming method according to claim 1, wherein said forming a coating film includes forming an antireflection film or a pattern transfer film on the processed film and then forming the resist film on the newly formed film.

8. The pattern forming method according to claim 1, wherein said exposing the resist film to form a desired pattern includes causing the underside of the substrate to make contact with a plurality of chuck pins.

9. A pattern forming method comprising:
not only heating a substrate from below the underside of the substrate with a heat plate and supplying a material gas for a surface hydrophobizing process to the surface of the substrate but also exhausting the material gas from outside the periphery of the substrate and further exhausting the material gas flowed to the underside of the substrate, thereby forming a processed film on the surface of the substrate to improve the adhesion of the substrate to a resist film;
causing the central part of the underside of the substrate to stick fast to a turntable and rotating the substrate and, at the same time, supplying hydrofluoric acid solution, ammonium fluoride solution, hydrofluoric acid gas, or ammonium fluoride gas to the underside of the substrate, thereby removing the processed film formed on the underside of the substrate by the surface hydrophobizing process;
forming on the processed film a coating film including at least a resist film;
exposing the resist film to form a desired pattern; and
developing the pattern-formed resist film.

10. The pattern forming method according to claim 9, wherein the processed film is composed of a silazane compound film.

11. The pattern forming method according to claim 9, wherein said exhausting the material gas flowed to the underside of the substrate when the processed film has been formed includes exhausting the material gas outside the area where the underside of the substrate sticks fast to the turntable and inside the periphery of the substrate, when removing the processed film.

12. The pattern forming method according to claim 9, wherein the said forming a coating film includes forming the resist film directly on the processed film.

13. The pattern forming method according to claim 10, wherein said forming a coating film includes forming an antireflection film or a pattern transfer film on the processed film and then forming the resist film on the newly formed film.

14. The pattern forming method according to claim 10, wherein said exposing the resist film to form a desired pattern includes causing the underside of the substrate to make contact with a plurality of chuck pins.

15. A processed film forming apparatus comprising:
a heat plate which is provided in a container and which has a substrate placed above the plate with a specific gap between the plate and the underside of a substrate and heats the substrate from below the underside;
a gas supplying mechanism which supplies to the surface of the substrate a processed film material gas for improving the adhesion of the substrate to resist;
a first gas exhaust mechanism which exhausts the gas supplied to the surface of the substrate from outside the periphery of the substrate; and
a second gas exhaust mechanism which is provided at the underside of the substrate and exhausts the material gas flowed to the underside of the substrate.

16. The processed film forming apparatus according to claim 15, wherein the second gas exhaust mechanism is provided in such a manner that it penetrates the heat plate.

17. The processed film forming apparatus according to claim 15, wherein the second gas exhaust mechanism is composed of a plurality of exhaust pipes which are provided in such a manner that the openings of the pipes face the underside of the substrate and that the pipes are arranged in positions on a circular arc with its axis perpendicular to the substrate in the center.
